(19) United States
(12) Patent Application Publication
(10) Pub. No.: US 2026/0136902 A1
(43) Pub. Date: May 14, 2026

(54) INTERCONNECT STRUCTURE INCLUDING HYBRID VIA AND METHOD FOR MANUFACTURING THE SAME

(71) Applicant: TAIWAN SEMICONDUCTOR MANUFACTURING COMPANY, LTD., Hsinchu (TW)

(72) Inventor: Chuan-Pu CHOU, Hsinchu (TW)

(73) Assignee: TAIWAN SEMICONDUCTOR MANUFACTURING COMPANY, LTD., Hsinchu (TW)

(21) Appl. No.: 18/947,052

(22) Filed: Nov. 14, 2024

(51) Int. Cl. H01L 21/768; H01L 23/522; H01L 23/532

(52) U.S. Cl. CPC H10W 20/056; H10W 20/033; H10W 20/072; H10W 20/075; H10W 20/42; H10W 20/46; H10W 20/47

(57) ABSTRACT

A method for manufacturing an interconnect structure, includes: forming a first stack on a base structure, the first stack including a first conductive line and a first cap portion which is formed on the first conductive line; forming a second stack on the base structure, the second stack being spaced apart from the first stack by a dielectric portion, the second stack including a second conductive line, a second cap portion which is formed on the second conductive line, and a lower conductive via which is formed in the second cap portion; forming a patterned etch stop layer on the first stack, the second stack and the dielectric portion so that the lower conductive via is exposed from the patterned etch stop layer and the second conductive line is prevented from being exposed from the patterned etch stop layer; and forming an upper conductive via on the lower conductive via.

### BACKGROUND

With rapid development of semiconductor technology, an increasing number of devices with different functions are being integrated in an integrated circuit, and thus the complexity of integrated circuit design is increased. For a back-end interconnecting structure, dimension of conductive features (e.g., metal lines and metal vias) therein is becoming smaller, and pattern density of the conductive features is becoming higher. Thus, in the back-end interconnecting structure with high pattern density, prevention of current leakage between two adjacent ones of the conductive features becomes more important. Therefore, methods for manufacturing the back-end interconnecting structure with high pattern density, low current leakage and high reliability are being continuously developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2 to 32 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In the process of forming a conductive via on one of conductive lines where the conductive via is at a level higher than a level of the one of conductive lines, firstly, an upper dielectric portion is formed on a lower dielectric portion in which the conductive lines are formed, the upper dielectric portion is then patterned to form an via opening to expose the one of the conductive lines, and then a conductive material is deposited to fill the via opening, thereby obtaining the conductive via. In the case that the lower dielectric portion is exposed to the via opening due to circuit layout design or process variation, the lower dielectric portion may be over etched during formation of the via opening. That is, a spike-shaped or a tiger tooth-shaped recess, which is indented from an upper surface of the lower dielectric portion along an inner contour of the via opening, may be formed. After the deposition of the conductive material, a spike-shaped or a tiger tooth-shaped conductive feature is formed between the one of the conductive lines and an adjacent one of the conductive lines, which may reduce a breakdown voltage (which may be also referred to as a via-to-line breakdown voltage) between the conductive via and the adjacent one of the conductive lines. Therefore, the present disclosure is directed to methods for manufacturing an interconnect structure. A via-to-line breakdown voltage is not adversely affected even if a spike-shaped or a tiger tooth-shaped conductive feature is formed due to circuit layout design or process variation.

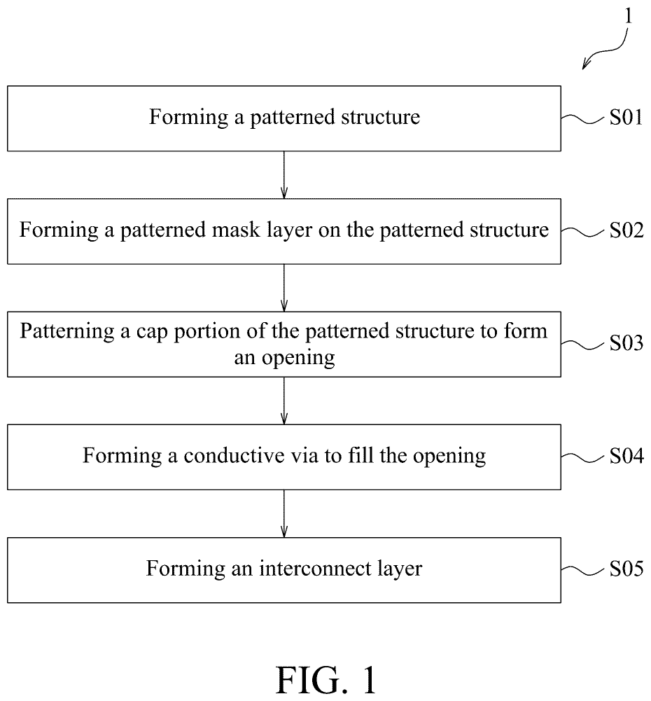

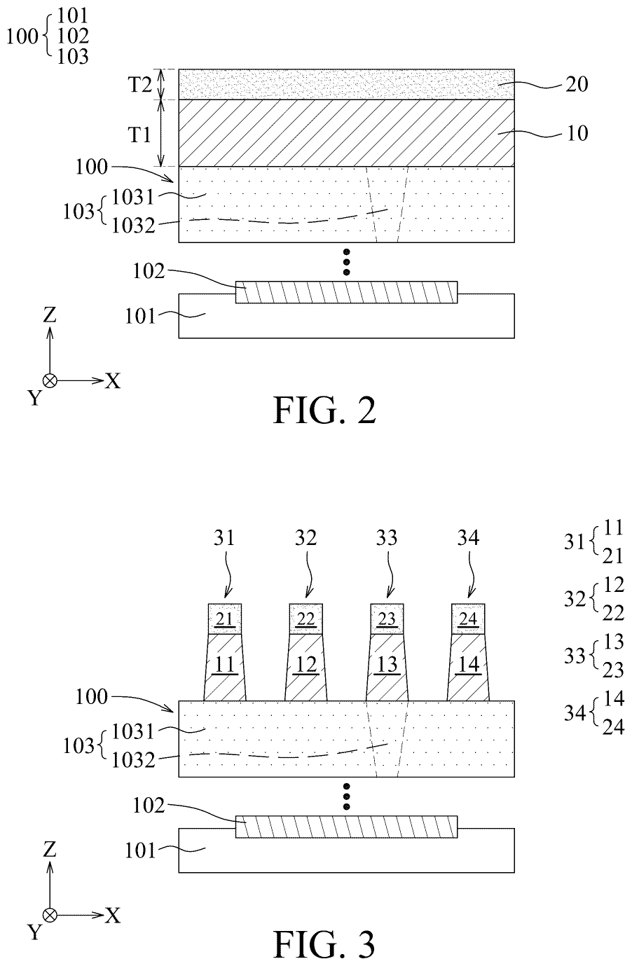

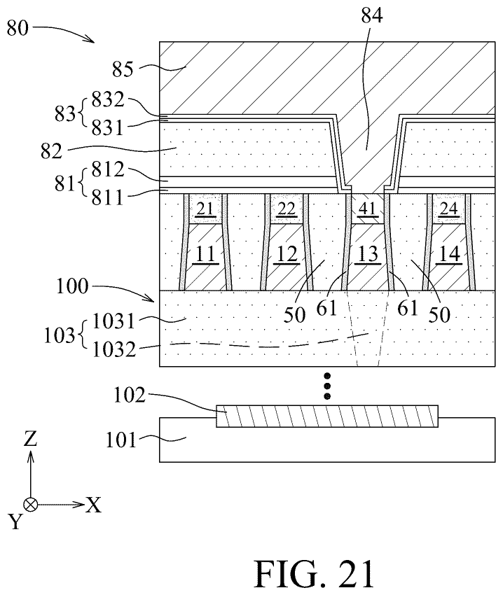

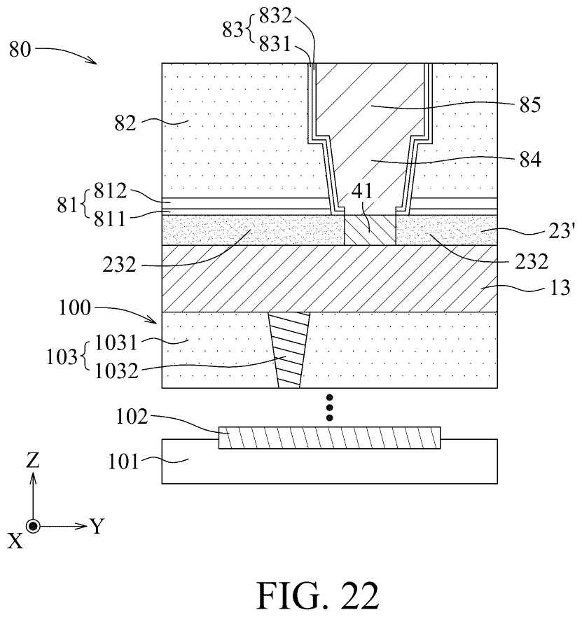

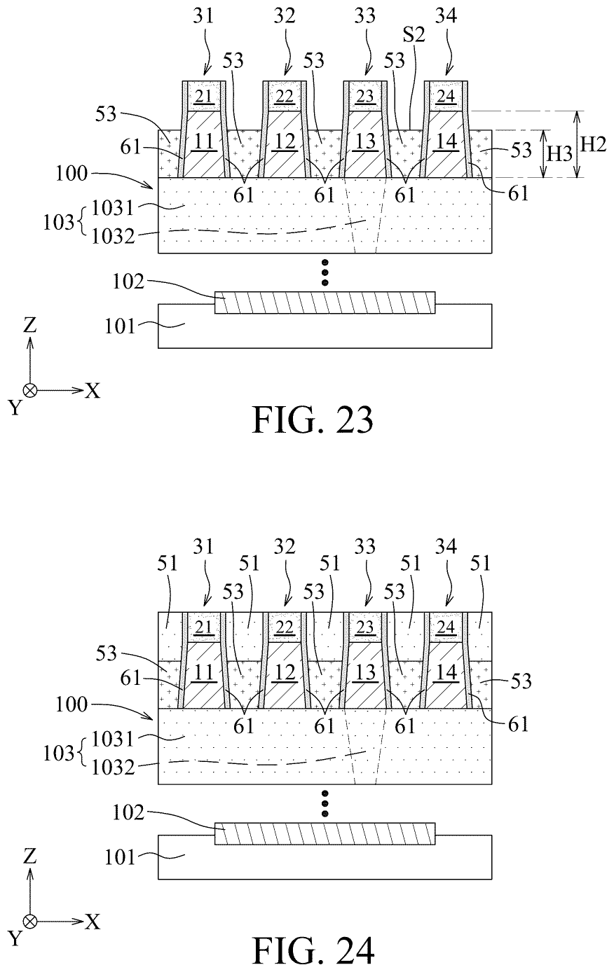

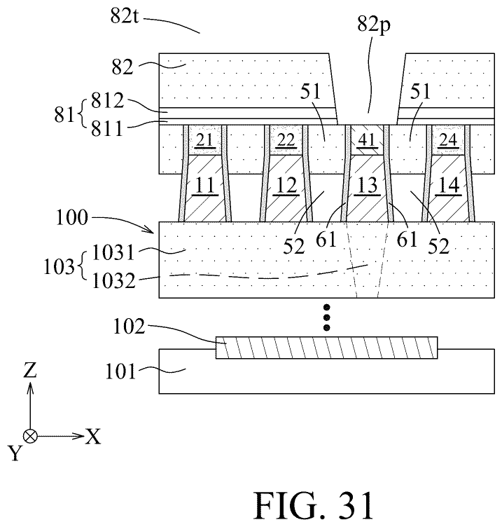

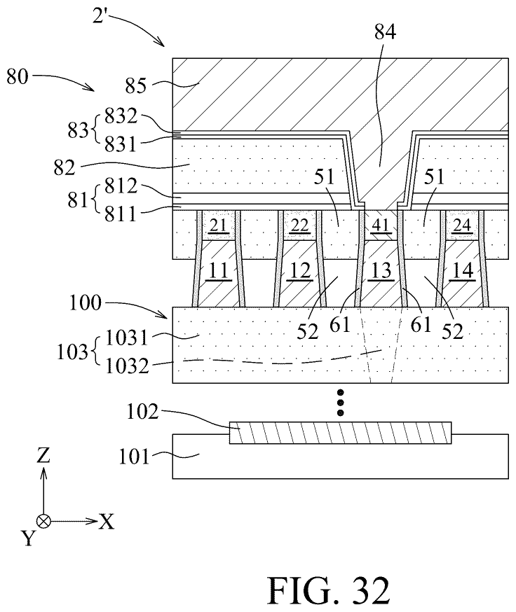

FIG. 1 is a flow diagram illustrating a method 1 for manufacturing an interconnect structure (e.g., an interconnect structure 2 shown in FIGS. 21 and 22 or an interconnect structure 2′ shown in FIG. 32) which is formed on a base structure in accordance with some embodiments. The method 1 may include steps S01 to S05. FIGS. 2 to 22 are schematic views illustrating intermediate stages of the method 1 in accordance with some embodiments, in which the interconnect structure 2 is formed, and FIGS. 23 to 32 are schematic views illustrating intermediate stages of the method 1 in accordance with some other embodiments, in which the interconnect structure 2′ is formed.

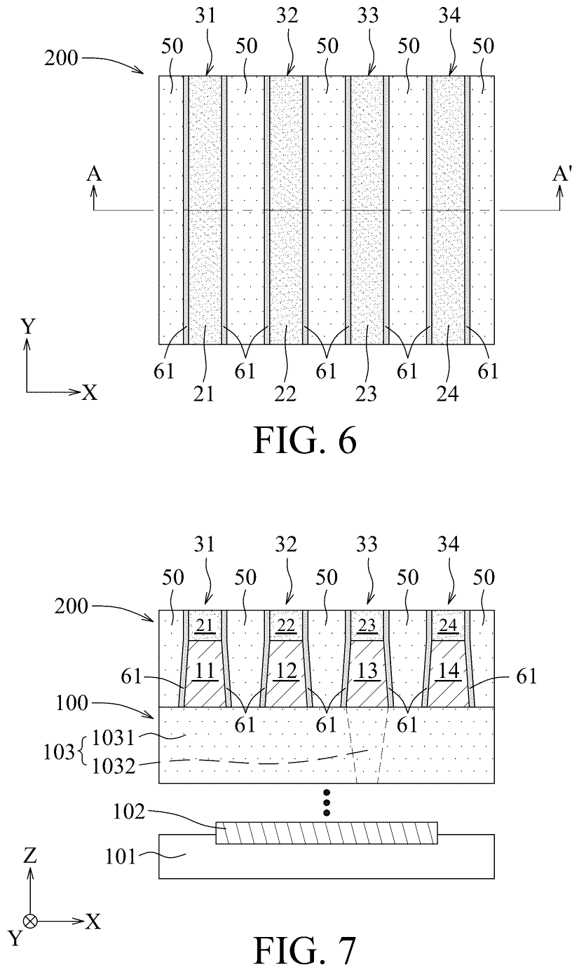

Referring to FIG. 1 and the examples illustrated in FIGS. 2 to 7, the method 1 begins at step S01, where a patterned structure 200 is formed on a base structure 100. FIG. 6 is a schematic top view illustrating the patterned structure 200 in accordance with some embodiments. FIG. 7 is a schematic sectional view (an X-cut view) taken along line A-A′ of FIG. 6 to illustrate the patterned structure 200 and the base structure 100 located therebeneath in accordance with some embodiments. FIGS. 2 to 5 (each of which is also an X-cut view) respectively illustrate four possible intermediate states in step S01 in accordance with some embodiments.

In some embodiments, the base structure 100 is a device wafer including active devices (for example, transistors, diodes, or the like), passive devices (for example, capacitors, inductors, resistors, or the like), memory devices, decoders, amplifiers, or combinations thereof. In some embodiments, the base structure 100 includes a substrate 101, a plurality of semiconductor devices 102 (one of which is exemplarily shown in FIG. 2) formed on the substrate 101, and an interconnect layer 103 formed on the semiconductor device 102.

In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations (not shown) to separate the semiconductor device 102 from adjacent ones of the semiconductor devices. In some embodiments, the trench isolations may each be a shallow trench isolation (STI), a deep trench isolation (DTI), or other suitable structures. In some embodiments, the trench isolations may include silicon oxide, silicon nitride, silicon oxynitride, other low-k (low-dielectric constant) dielectric materials, or combinations thereof.

In some embodiments, the semiconductor device 102 may include a transistor, but is not limited thereto. The transistor may be configured as a planar transistor, a fin-type field-effect transistor (FinFET), a gate-all-around field-effect transistor (GAAFET), a forksheet field-effect transistor, a complementary field-effect transistor (CFET), or other transistors with suitable configuration.

In some embodiments, the interconnect layer 103 includes a dielectric layer 1031 and conductive features 1032 (one of which is exemplarily shown in FIG. 2) formed in the dielectric layer 1031. The semiconductor device 102 may be electrically connected to an external circuit through the conductive feature 1032. In some embodiments, the dielectric layer 1031 includes or is made of a low-k dielectric material. In some embodiments, the dielectric layer 1031 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1031 are within the contemplated scope of the present disclosure. In some embodiments, the conductive feature 1032 may be configured as a conductive via which is connected to a conductive line (not shown) that is located therebeneath. In some other embodiments, the conductive feature 1032 may be configured as a conductive contact which is connected to a gate electrode or a source/drain portion of the semiconductor device 102. In some embodiments, the conductive feature 1032 includes or is made of Co, Cu, Ni, Ru, W, Mo, Ti, Al, Ir, Rh, Zr, Ta, Zn, alloys thereof, graphene, or combinations thereof. Other conductive materials suitable for the conductive feature 1032 are also within the contemplated scope of the present disclosure. In some embodiments, the conductive feature 1032 may be formed by a single damascene process.

Referring to FIGS. 6 and 7, the patterned structure 200 includes stacks 31, 32, 33, 34 and dielectric portions 50. The stacks 31, 32, 33, 34 are elongated in a Y direction and which are spaced apart from each other in an X direction transverse to the Y direction. The dielectric portions 50 are disposed to alternate with the stacks 31, 32, 33, 34 in the X direction, so that two adjacent ones of the stacks 31, 32, 33, 34 are spaced apart by a corresponding one of the dielectric portions 50. The dielectric portions 50 may be also referred to as lower dielectric portions. The number of the stacks 31, 32, 33, 34 and the dielectric portions 50 is not limited to the number shown in FIG. 6, and may vary according to practical applications. In some embodiments, the patterned structure 200 further includes barrier portions 61, each of which is disposed to separate one of the stacks 31, 32, 33, or 34 from a corresponding adjacent one of the dielectric portions 50. The details of the stacks 31, 32, 33, 34, the dielectric portions 50 and the barrier portions 61 are described hereinafter.

In some embodiments, formation of the patterned structure 200 may include multiple sub-steps as described in the following.

Firstly, as shown in FIG. 2, a conductive layer 10 and a cap layer 20 are sequentially formed on the base structure 100 in a Z direction transverse to the X and Y directions. In some embodiments, the X, Y and Z directions are perpendicular to each other. Possible conductive materials suitable for the conductive layer 10 are similar to those for the conductive feature 1032, and thus the details thereof are omitted for the sake of brevity. In some embodiments, the cap layer 20 may be configured as a single layer structure, as shown in FIG. 2. In some other embodiments not shown herein, the cap layer 20 may be configured as a multi-layered structure which includes multiple sub-layers stacked on each other. The cap layer 20 includes or is made of a low-k dielectric material. In some embodiments, the cap layer 20 includes or is made of silicon oxide, silicon nitride, silicon oxycarbide (which may be also referred as to as oxygen-doped siliconcarbide, abbreviated as ODC or SiOC), silicon oxynitride (SiON), silicon carbon nitride (which may be also referred to as nitrogen-doped silicon carbide, abbreviated as NDC or SiCN), silicon oxide formed from tetraethoxysilane (TEOS), or combinations thereof. Other low-k dielectric materials suitable for the cap layer 20 are within the contemplated scope of the present disclosure. In some embodiments, a ratio (T2/T1) of a thickness (T2) of the cap layer 20 to a thickness (T1) of the conductive layer 10 may range from about ½ to about ¼. A sum of the thickness (T1) of the conductive layer 10 and the thickness (T2) of the cap layer 10 may vary according to specification of circuit design at different technology nodes. In some embodiments, each of the conductive layer 10 and the cap layer 20 may be formed by atomic layer deposition (ALD), physical vapor deposition (PVD), chemical vapor deposition process (CVD), or other suitable deposition techniques.

Afterwards, as shown in FIG. 3, a patterning process is performed such that the conductive layer 10 and the cap layer 20 are patterned into the stacks 31, 32, 33, 34, and such that portions of the dielectric layer 1031 are exposed from the stacks 31, 32, 33, 34. Each of the stacks 31, 32, 33, 34 includes a conductive line 11, 12, 13, or 14 which is formed from the conductive layer 10, and a cap portion 21, 22, 23, or 24 which is formed from the cap layer 20 and which is disposed on the conductive line 11, 12, 13, or 14 opposite to the base structure 100. In some embodiments, the patterning process includes a photolithography process and a subsequent etching process. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones. Each of the cap portions 21, 22, 23, 24 has an upper surface and a lower surface which are respectively distal from and proximate to the base structure 100. In some embodiments, the upper surfaces of the cap portions 21, 22, 23, 24 are flush with each other, and the lower surfaces of the cap portions 21, 22, 23, 24 are flush with each other.

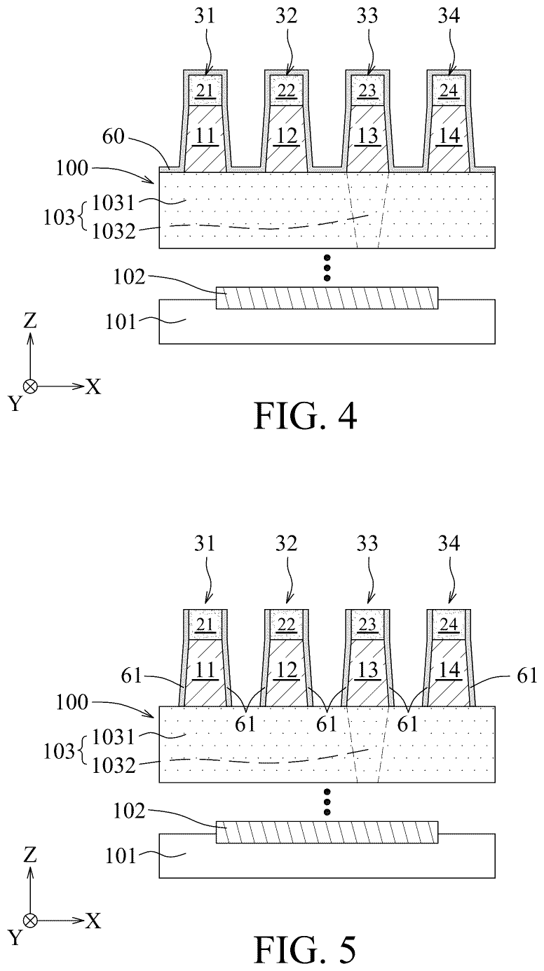

Next, as shown in FIG. 4, a barrier layer 60 is formed on the stacks 31, 32, 33, 34 and the exposed portions of the dielectric layer 1031 by ALD, CVD, PVD, or other suitable deposition techniques. In some embodiments, the barrier layer 60 includes or is made of a dielectric material that is different from the dielectric material of the cap layer 20, and thus the barrier layer 60 and the cap layer 20 have different etching selectivities or different etching rates. Possible materials suitable for the barrier layer 60 are similar to those for the cap layer 20, and thus the details thereof are omitted for the sake of brevity. In some embodiments, the barrier layer 60 has a thickness ranging from about 10 Å to about 40 Å, but other ranges of values are also within the contemplated scope of the present disclosure.

Then, as shown in FIG. 5, an anisotropic etching process is performed on the barrier layer 60 to remove horizontal portions of the barrier layer 60, while vertical portions of the barrier 60 respectively remain at side surfaces of the stacks 31, 32, 33, 34, and respectively serve as the barrier portions 61.

Thereafter, as shown in FIGS. 6 and 7, the dielectric portions 50 are formed, thereby obtaining the patterned structure 200. The dielectric portions 50 each includes or is made of a dielectric material that is different from the dielectric material of the cap layer 20, and thus the dielectric portions 50 and the cap layer 20 have different etching selectivities or different etching rates. The dielectric material of each of the dielectric portions 50 may be the same as or different from the dielectric material of the barrier layer 60. Possible dielectric materials suitable for the dielectric portions 50 are similar to those for the cap layer 20, and thus the details thereof are omitted for the sake of brevity. In some embodiments, formation of the dielectric portions 50 includes forming a dielectric layer (not shown) for forming the dielectric portions 50 on the structure shown in FIG. 5 using ALD, PVD, CVD or other suitable deposition techniques, and performing a planarization process (e.g., a chemical mechanical polishing process) on the dielectric layer to expose the cap portions 21, 22, 23, 24 and the barrier portions 61.

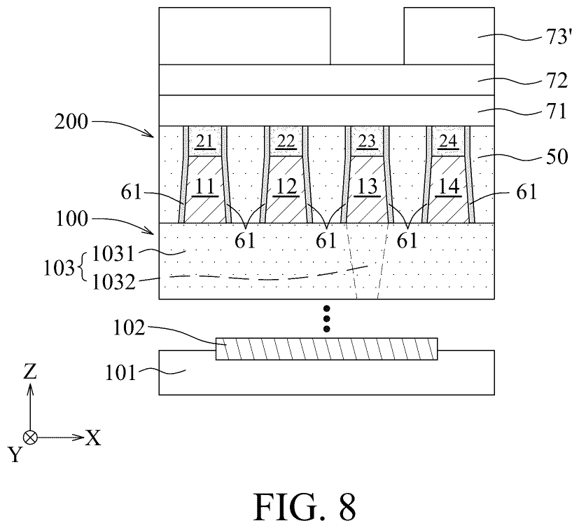

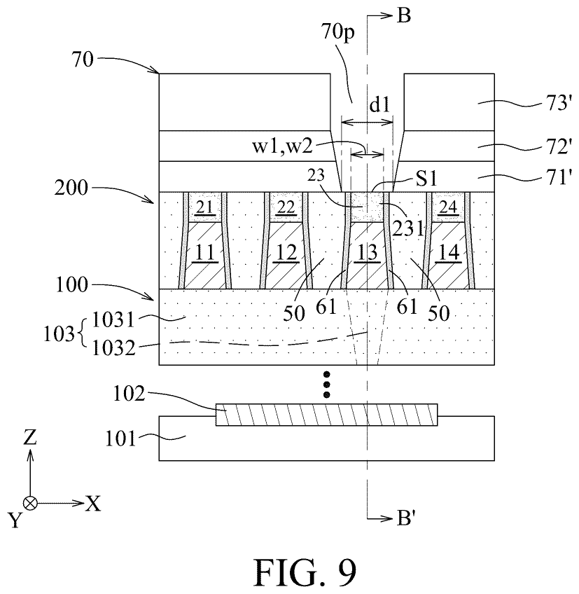

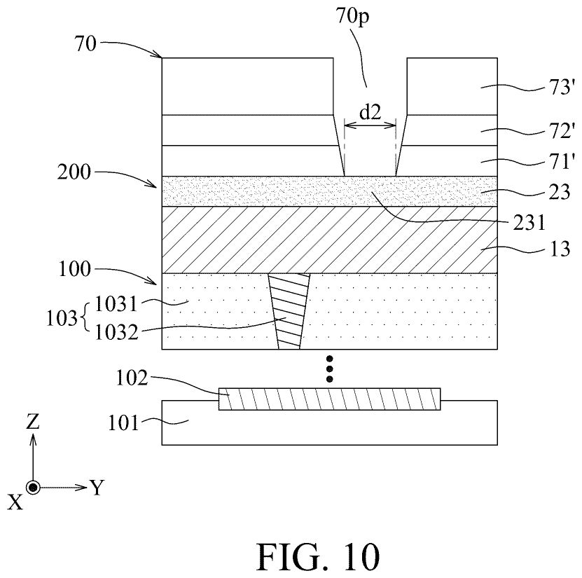

Referring to FIG. 1 and the examples illustrated in FIGS. 8 to 10, the method 1 proceeds to step S02, where a patterned mask layer 70 is formed on the patterned structure 200. The patterned mask layer 70 is formed with an opening 70p so that a predetermined part 231 of the cap portion 23 is exposed from the patterned mask layer 70. FIG. 9 is a schematic sectional view similar to that of FIG. 7, but illustrating the structure after step S02 in accordance with some embodiments. FIG. 10 is a schematic sectional view (a Y-cut view) taken along line B-B′ of FIG. 9 in accordance with some embodiments. FIG. 8 illustrates one possible intermediate state in step S02 in accordance with some embodiments.

In some embodiments, as shown in FIGS. 9 and 10, the patterned mask layer 70 is configured as a tri-layered structure. In some embodiments not shown herein, the patterned mask layer 70 may be configured as a bi-layered structure or a single photoresist layer. In some embodiment, formation of the patterned mask layer 70 may include multiple sub-steps as described in the following.

Firstly, a bottom layer 71 (see FIG. 8), a middle layer 72 (see FIG. 8) and a top layer (not shown) are sequentially formed on the patterned structure 200 by ALD, CVD, PVD, a spin-on coating process, other suitable deposition techniques, or combinations thereof. The bottom layer 71 includes or is made of an organic material (CₓH_{y}O_{z}). The middle layer 72 includes or is made of an inorganic material, such as silicon oxide, silicon nitride, silicon oxynitride, metal nitride (e.g., aluminum nitride, tungsten nitride), or other suitable materials. The top layer includes or is made of a photosensitive material.

Afterwards, as shown in FIG. 8, the top layer is patterned by a photolithography process to form a patterned top layer 73′.

Next, as shown in FIGS. 9 and 10, the middle layer 72 and the bottom layer 71 are patterned by an etching process using the patterned top layer 73′ as a mask to respectively form a patterned middle layer 72′ and a patterned bottom layer 73′, and the opening 70p is thus formed in the patterned mask layer 70. The patterned mask layer 70 includes the patterned top layer 73′, the patterned middle layer 72′ and the patterned bottom layer 71′. In some embodiments not shown herein, the patterned top layer 73′ may be partially or completely removed after formation of the opening 70p.

In some embodiments, a dimension (d1, measured in the X direction) of a bottom of the opening 70p is greater than a width (w1, measured in the X direction) of the upper surface of the cap portion 23, so that a width (w2, measured in the X direction) of an upper surface S1 of the predetermined part 231, which is exposed from the opening 70p, is equal to the width (w1) of the upper surface of the cap portion 23. In such case, two adjacent ones of the barrier portions 61, which are respectively disposed at two opposite sides of the cap portion 23 in the X direction, may be exposed from the opening 70p. In some embodiments, two adjacent ones of the dielectric portions 50, which are respectively disposed at the two opposite sides of the cap portion 23, may be partially exposed from the opening 70p. In some embodiments, the dimension (d1) of the bottom of the opening 70p may be the same as or different from a dimension (d2, measured in the X direction) of the bottom of the opening 70p.

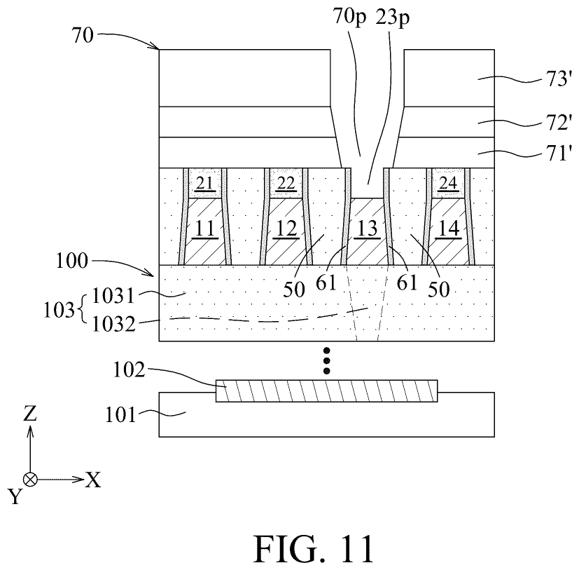

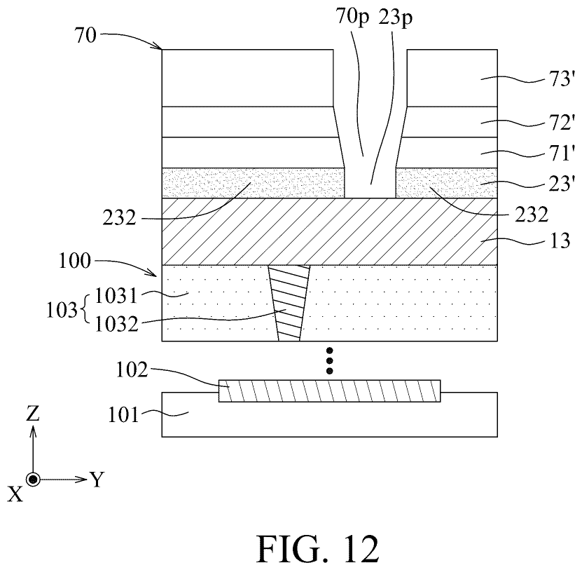

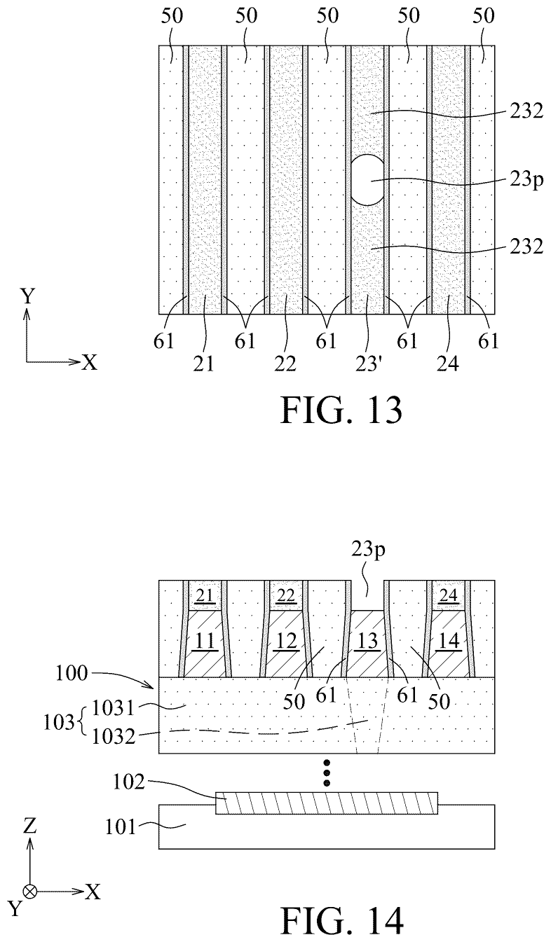

Referring to FIG. 1 and the examples illustrated in FIGS. 11 to 14, the method 1 proceeds to step S03, where the cap portion 23 (see FIGS. 9 and 10) is patterned using the patterned mask layer 70 as a mask to form an opening 23p therein. FIGS. 13 and 14 are schematic views respectively similar to those of FIGS. 6 and 9, but illustrating the structure after step S03 in accordance with some embodiments. FIGS. 11 and 12, which are an X-cut view and a Y-cut view respectively similar to those of FIGS. 9 and 10, illustrate one possible intermediate state in step S03 in accordance with some embodiments.

Firstly, as shown in FIGS. 11 and 12, the predetermined part 231 of the cap portion 23 (see FIGS. 9 and 10), which is exposed from the patterned mask layer 70, is removed by an etching process to form the opening 23p, such that a portion of the conductive line 13 is exposed from the opening 23p. The patterned cap portion is denoted by the numeral 23′ and includes two cap parts 232 separated from each other in the Y direction by the opening 23p. Since the materials of the cap portion 23 and the dielectric portions 50 and the barrier portions 61 have different etching selectivities, the two adjacent ones of the barrier portions 61 and the two adjacent ones of the dielectric portions 50, which are also exposed from the patterned mask layer 70, are substantially intact during the removal of the predetermined part 231 of the cap portion 23.

Afterwards, as shown in FIGS. 13 and 14, the patterned mask layer 70 is removed by, for example, but not limited to, an ashing process, a photoresist stripping process, an etching process, or combinations thereof.

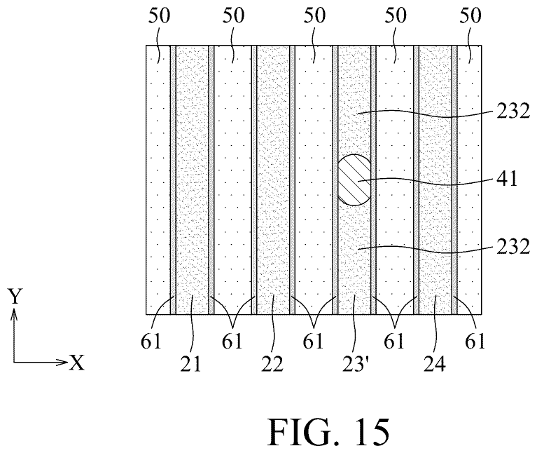

Referring to FIG. 1 and the examples illustrated in FIGS. 15 to 17, the method 1 proceeds to step S04, where a conductive via 41 is formed to fill the opening 23p (see FIGS. 13 and 14). As such, the predetermined part 231 of the cap portion 23 (see FIGS. 9 and 10) is replaced with the conductive via 41. The conductive via 41 may be also referred to as a lower conductive via. FIGS. 15, 16 and 17 are schematic views respectively similar to those of FIGS. 13, 14 and 12, but illustrating the structure after step S04 in accordance with some embodiments.

Possible conductive materials suitable for the conductive via 41 are similar to those for the conductive feature 1032, and thus the details thereof are omitted for the sake of brevity. In some embodiments, formation of the conductive via 41 includes forming a conductive layer (not shown) for forming the conductive via 41 on the structure shown in FIG. 14 by electrochemical plating, electroless deposition, ALD, CVD, PVD, or other suitable deposition techniques such that the conductive layer fills the opening 23p, and performing a planarization process (e.g., a chemical mechanical polishing process) on the conductive layer until the dielectric portions 50, the cap portions 21, 22, 23′, 24 and the barrier portions 61 are exposed. The conductive via 41 has an upper surface and a lower surface which are respectively distal from and proximate to the base structure 100. In some embodiments, the upper surface of the conductive via 41 is flush with the upper surface of each of the cap portions 21, 22, 23′, 24. It is noted that a height (H0) of the conductive via 41 and a height (H2) of each of the conductive lines 11, 12, 13, 14 mainly depend on the thickness (T2) of the cap layer 20 and the thickness (T1) of the conductive layer 10, respectively (see also FIG. 2). That is, a ratio (H0/H2) of the height (H0) of the conductive via 41 to the height (H2) of each of the conductive lines 11, 12, 13, 14 may be substantially equal to the ratio (T2/T1) of the thickness (T2) of the cap layer 20 to the thickness (T1) of the conductive layer 10.

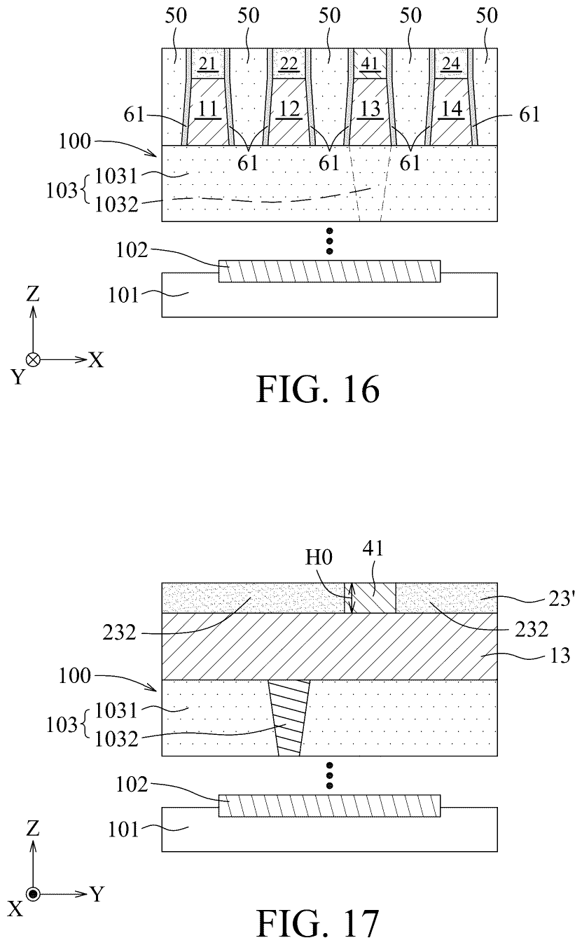

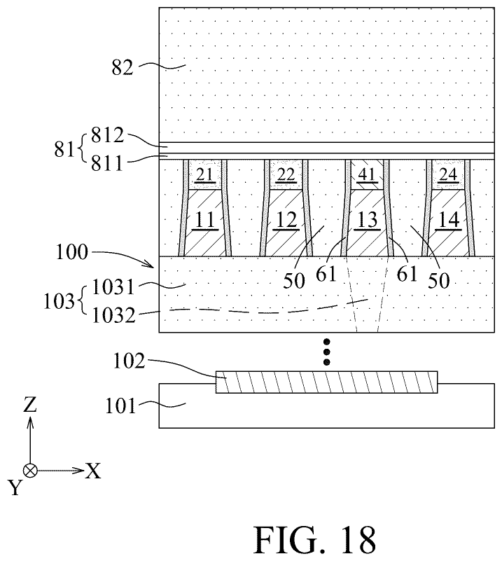

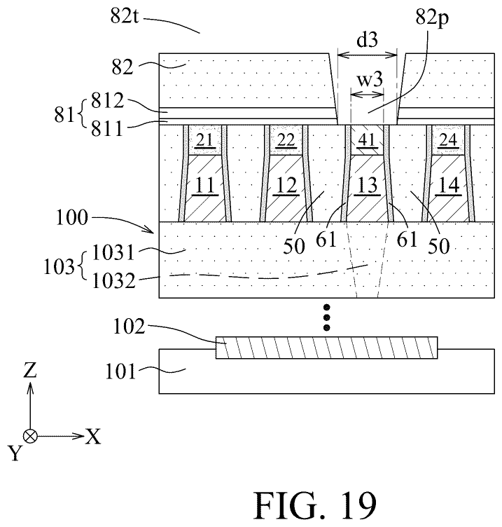

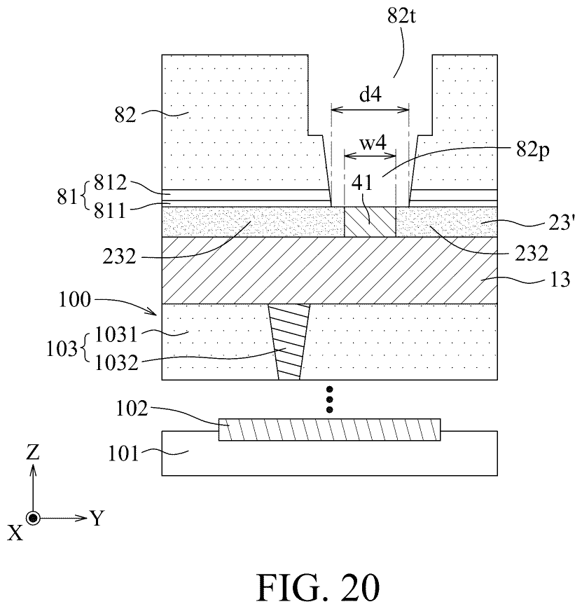

Referring to FIG. 1 and the examples illustrated in FIGS. 18 to 22, the method 1 proceeds to step S05, where an interconnect layer 80 is formed, and the interconnect structure 2 is thus obtained. FIGS. 21 and 22 are an X-cut view and a Y-cut view respectively similar to those of FIGS. 16 and 17, but illustrating the structure after step S05 in accordance with some embodiments. FIGS. 18 to 20 illustrates two possible intermediate states in step S05 in accordance with some embodiments, in which FIGS. 18 and 19 are X-cut views, and FIG. 20 is a Y-cut view.

In some embodiment, formation of the interconnect layer 80 may include multiple sub-steps as described in the following.

Firstly, as shown in FIG. 18, an etch stop layer 81 and a dielectric layer 82 (which may be also referred to as an upper dielectric portion) is sequentially formed on the structure shown in FIG. 16 by ALD, CVD, PVD, or other suitable deposition techniques. In some embodiments, the etch stop layer 81 may be configured as a single layer structure or a multi-layered structure which includes sub-layers 811, 812 stacked on each other. In some embodiments, the sub-layer 811 includes or is made of metal oxide which includes oxides of aluminum, zirconium, hafnium, other suitable materials, or combinations thereof. In some embodiments, the sub-layer 812 includes or is made of silicon carbon nitride (NDC), silicon oxycarbide (ODC), silicon oxide, silicon nitride, silicon oxide formed from tetraethoxysilane (TEOS), other suitable materials, or combinations thereof. In some embodiments, the etch stop layer 81 has a thickness ranging from about 10 Å to about 200 Å, but other ranges of values are also within the contemplated scope of the present disclosure.

Afterwards, as shown in FIG. 19 and FIG. 20 (which is a schematic sectional view subsequent to that of FIG. 17), a trench 82t is formed in an upper region of the dielectric layer 82, and an opening 82p is formed in a lower region of the dielectric layer 82 beneath the trench 82t. The trench 82t is elongated in the X direction. The opening 82p is in spatial communication with the trench 82t and extends through the etching stop layer 81 so as to permit the conductive via 41 to be exposed from the opening 82p and the trench 82t. Formation of the trench 82t and the opening 82p includes multiple patterning processes. For example, after the upper region of the dielectric layer 82 is patterned to form the trench 82t, a patterned masking layer (not shown) is formed on the patterned upper region of the dielectric layer 82, followed by removing a portion of the lower region of the dielectric layer 82, which is exposed from the patterned mask layer, so as to form the opening 82p.

In some embodiments, a dimension (d3, measured in the X direction) of a bottom of the opening 82p is greater than a width (w3, measured in the X direction) of the upper surface of the conductive via 41, and a dimension (d4, measured in the Y direction) of the bottom of the opening 82p is greater than a width (w4, measured in the Y direction) of the upper surface of the conductive via 41, so as to permit the conductive via 41 to be completely exposed from the opening 82p under normal process variation (e.g., alignment shift during an exposure process). In some embodiments, the dimension (d3) may be about 1.5 times to about 2.5 times greater than the width (w3). In some embodiments, the dimension (d4) may be about 1.5 times to about 2.5 times greater than the width (w4). It is noted that the conductive line 13 is prevented from being exposed from the opening 82p.

Next, as shown in FIGS. 21 and 22, a liner layer 83 is selectively formed along an inner surface defined by the trench 82t and the opening 82p without being formed on the upper surface of the conductive via 41. In some embodiments, the liner layer 83 may be configured as a single layer structure or a multi-layered structure which includes sub-layers 831, 832 stacked on each other. In some embodiments, the liner layer 83 includes or is made of tantalum, tantalum nitride, aluminum, aluminum oxide, titanium, titanium nitride, manganese nitride, cobalt, niobium, lead, platinum, nickel, scandium, ruthenium, molybdenum, chromium, titanium tungsten, tungsten nitride, tungsten, iridium, rhodium, graphene, or combinations thereof. With the provision of the liner layer 83, an adhesion between the dielectric layer 82 and a conductive material to be subsequently filled in the trench 82t and the opening 82p may be improved. Furthermore, the elements (for example, metal ions/atoms) of the conductive material filled in the trench 82t and the opening 82p may be prevented from diffusing into the dielectric layer 82. In some embodiments, selective formation of the liner layer 83 includes selectively forming a block layer (not shown) on the upper surface of the conductive via 41, depositing material(s) of the liner layer 83 along the inner surface defined by the trench 82t and the opening 82p, and removing the block layer by, for example, a plasma treatment or a thermal treatment, such that the material(s) for forming the liner layer 83 deposited over the block layer is(are) removed simultaneously. In some embodiments, the block layer may be made of a self-assembled monolayer (SAM) which can be selectively formed on a metallic material or a native oxide layer which is naturally formed on the metallic material. In some embodiments, the SAM material includes a head group which contains phosphorus (P), sulfur(S) or silicon (Si), and a tail group which is connected to the head group and which contains an organic chain, such as hydrocarbon chain (CₓH_{y}) or the like. In some embodiments, the head group of SAM may include phosphate, sulfate, or silane-based materials. In some embodiments, SAM may include benzotriazole (BTA), phosphonic acid, octadecylphosphonic (ODPA), organosulfur compound, thiol (e.g., dodecanethiol, alkanethiol, or the like), etc. In some embodiments, a precursor gas used in the plasma treatment includes argon, nitrogen, ammonia, xenon, other suitable inert gases, or other gases suitable for removing the block layer. Then, a conductive via 84 (which may be also referred to as an upper conductive via) and a conductive line 85 are respectively formed to fill the opening 82p and the trench 82t. Possible conductive materials and processes suitable for the conductive via 84 and the conductive line 85 are similar to those for the conductive via 41, and thus the details thereof are omitted for the sake of brevity. In some embodiments, the conductive via 84 and the conductive via 41 may be together referred to as a hybrid via.

Since the upper surface of the conductive via 41 is ensured to be completely exposed from the opening 82p, a contact resistance between the conductive via 41 and the conductive via 84, which is formed in the opening 82p, can be minimized. Furthermore, since the conductive via 41 is self-aligned with the conductive line 13, a contact resistance between the conductive via 41 and the conductive line 13 can be also minimized.

Since the bottom of the opening 82p (see FIG. 19) is relatively large, the two adjacent ones of the dielectric portions 50 are also exposed from the opening 82p. In the case that a recess is downwardly indented from an upper surface of one of the two adjacent ones of the dielectric portions 50 and the recess is filled with the conductive material of the conductive via 84 to form a downwardly protruding conductive feature, the downwardly protruding conductive feature is located at a level adjacent to an interface between the conductive vias 41, 82 and is not located between the conductive line 13 and any one of the conductive lines 12, 14. Therefore, a via-to-line breakdown voltage between the conductive via 81 and the conductive line 12 (or conductive line 14) is not adversely affected.

In addition, the etch stop layer 81 is spaced apart by each the conductive lines 11, 12, 13, 14 by a distance which is substantially equal to a value of the thickness (T2) of the cap layer 20 (which is substantially equivalent to the height (H0) of the conductive via 41 or a height of each of the cap portions 21, 22, 23′, 24), and thus electric field lines between two adjacent ones of the conductive lines 11, 12, 13, 14 are less likely to pass through the etch stop layer 81, thereby reducing a parasitic capacitance between the two adjacent ones of the conductive lines 11, 12, 13, 14.

In some embodiments as described above, the interconnection layer 80 is formed by a dual damascene process, that is, the opening 82p and the trench 82t are filled with the conductive material(s) of the conductive via 84 and the conductive line 85 at the same time. In some other embodiments not shown herein, the interconnection layer 80 may be formed by two single damascene processes, or other suitable back-end-of-line (BEOL) techniques.

In the following, formation of the interconnect structure 2′ is described. Similar numerals from the above-mentioned embodiments have been used where appropriate, with some construction differences being indicated with different numerals. FIG. 32 is a schematic sectional view illustrating the interconnect structure 2′ formed on the base structure 100 in accordance with some other embodiments. The interconnect structure 2′ has a structure similar to that of the interconnect structure 2 shown in FIG. 21, but has difference in dielectric portions 50′. In the interconnect structure 2′, each of the dielectric portions 50′ includes an upper region 51 and a lower region 52 which are respectively distal from and proximate to the base structure 100. A dielectric constant of the upper region 51 is greater than a dielectric constant of the lower region 52. In some embodiments, the lower region 52 is an air gap region. A height (H1) of the lower region 52 is not greater than the height (H2) of each of the conductive lines 11, 12, 13, 14.

The semiconductor structure 2′ may be formed in a manner similar to the method 1 as described above, but has slight differences in step S01, in which a patterned structure 200′, which includes the dielectric portions 50′, is formed on the base structure 100. To be specific, formation of the dielectric portions 50′ may not be performed in the manner as described above with reference to FIG. 7. FIGS. 23 to 32 are schematic views illustrating intermediate stages of the method 1 in accordance with some other embodiments.

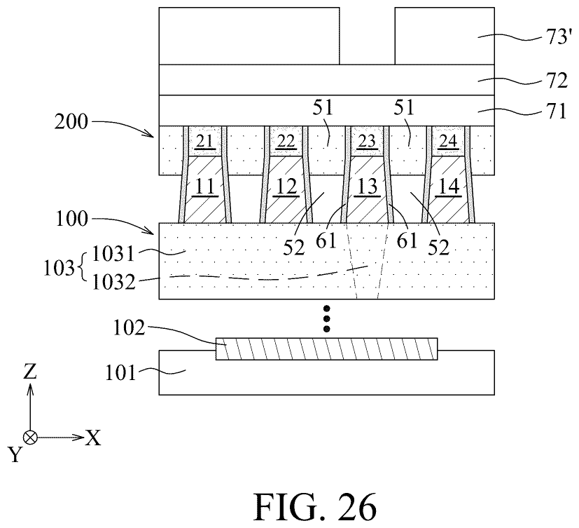

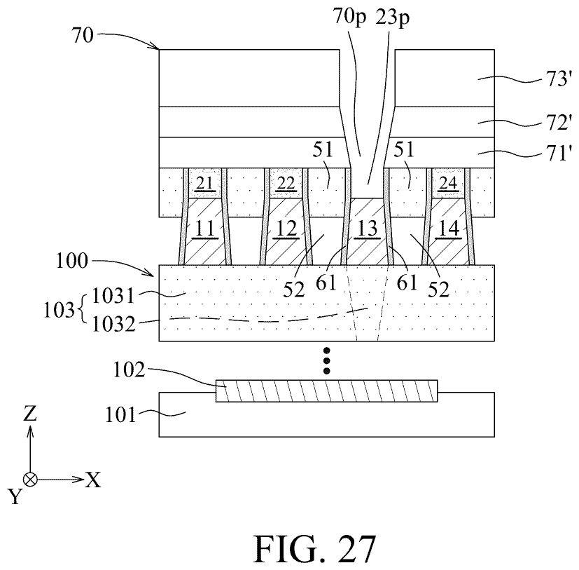

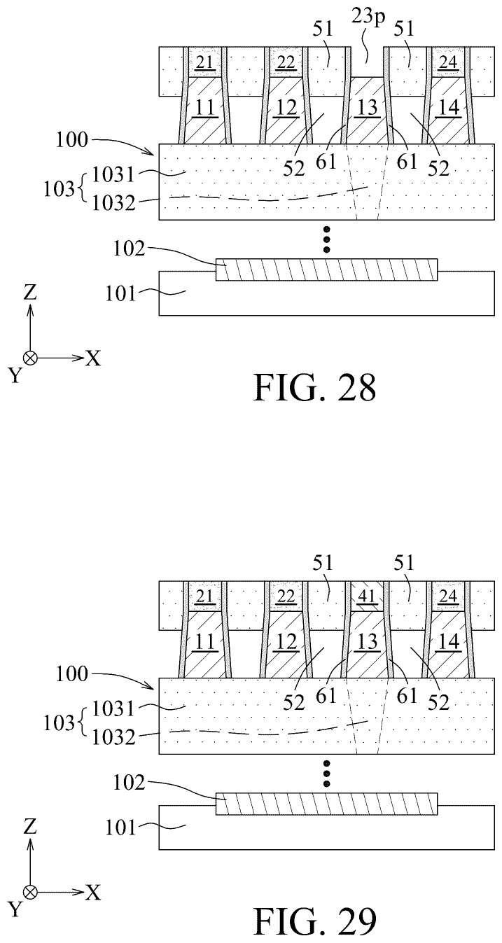

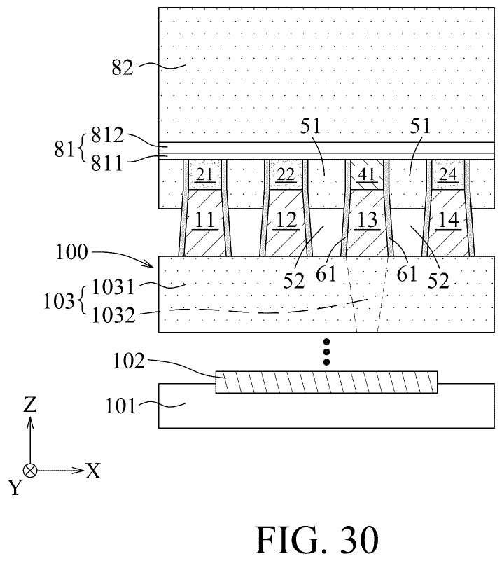

In the following, only the differences in step S01 will be described. Step S02 (the examples illustrated in FIGS. 26 and 27), step S03 (the example illustrated in FIG. 28 which is an X-cut view similar to that of FIG. 14), step S04 (the example illustrated in FIG. 29 which is an X-cut view similar to that of FIG. 16), and step S05 (the examples illustrated in FIGS. 30, 31 and 32 which are X cut views respectively similar to those of FIGS. 18, 19 and 21) are performed in a manner respectively similar to those as described above in steps S02 to S05 with reference to FIGS. 8 to 22, and thus the details thereof are omitted for the sake of brevity.

Referring to FIG. 23, after the stacks 31, 32, 33, 34 and the barrier portions 61 are formed, sacrificial regions 53 are formed. Each of the sacrificial regions 53 is formed between two adjacent ones of the conductive lines 11, 12, 13, 14. In some embodiments, each of the sacrificial regions 53 includes or is made of polyurea, polylactic acid, polycaprolactone, poly(ethylene oxide), polyacrylate, polyvinyl alcohol, or combinations thereof, but is not limited thereto. An upper surface S2 of each of the sacrificial regions 53 is at level not higher than that of the upper surface of each of the conductive lines 11, 12, 13, 14 relative to the base structure 100. In other words, a height (H3) of each of the sacrificial regions 53 is not greater than the height (H2) of each of the conductive lines 11, 12, 13, 14. In some embodiments, formation of the sacrificial regions 53 may include forming a sacrificial layer (not shown) for forming the sacrificial regions 53 on the structure shown in FIG. 5 using a spin-on coating process, followed by a curing process, and etching back the sacrificial layer by an etching process so as to form the sacrificial regions 53. Other techniques and/or materials suitable for forming the sacrificial regions 53 are within the contemplated scope of the present disclosure.

Referring to FIG. 24, the upper region 51 of each of the dielectric portions 50′ (see also FIG. 32) is formed on a respective one of the sacrificial regions 53, such that the upper region 51 of each of the dielectric portions 50′ is disposed between two corresponding adjacent ones of the cap portions 21, 22, 23, 24. The upper region 51 includes or is made of a dielectric material that is different from the dielectric material of the cap layer 20. Possible dielectric materials and processes suitable for the upper region 51 are similar to those for the dielectric portions 50, and thus the details thereof are omitted for the sake of brevity. An interface between the upper region 51 of each of the dielectric portions 50′ (see also FIG. 32) and the respective one of the sacrificial regions 53 is at a level not higher than a level of an interface between the cap portion 21, 22, 23, or 24 and the conductive line 11, 12, 13, or 14 of each of the stacks 31, 32, 33, 34 relative to the base structure.

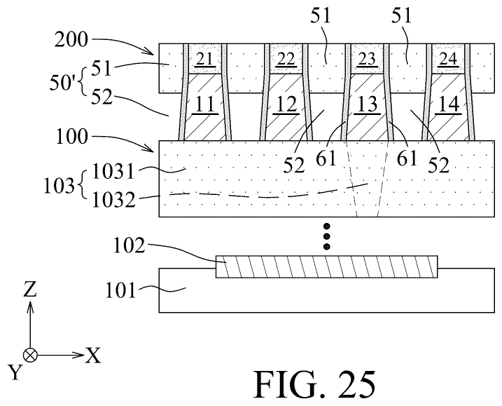

Referring to FIG. 25, after formation of the upper region 51, the sacrificial regions 53 are removed by a thermal treatment, an ultraviolet treatment, or a combination thereof so as to permit the sacrificial regions 53 to be decomposed, vaporized, and degassed through the upper region 51 of each of the dielectric portions 50′, thereby obtaining the lower region 52 of each of the dielectric portions 50′.

In some embodiments, some steps in the method 1 may be modified, replaced, or eliminated without departure from the spirit and scope of the present disclosure. In some alternative embodiments, the interconnecting structure 2, 2′ may further include additional features, and/or some features present in the interconnect structure 2, 2′ may be modified, replaced, or eliminated without departure from the spirit and scope of the present disclosure.

In summary, by performing a replacement process to replace the predetermined part 231 of the cap layer 20 with the conductive via 41 before formation of the etch stop layer 81, and by forming the conductive via 84 which extends through the etch stop layer 81 so as to connect the conductive via 84 to the conductive via 41, the interconnect structure 2, 2′ having an improved reliability and an improved via-to-line breakdown voltage can be obtained. In addition, a contact resistance between the conductive vias 41, 84 and a contact resistance between the conductive via 41 and the conductive line 13 are reduced or minimized, and a parasitic capacitance between two adjacent ones of the conductive lines 11, 12, 13, 14 is reduced. Furthermore, other techniques suitable for forming air gaps in the interconnect structure 2, 2′ may be integrated in the method of this disclosure.

In accordance with some embodiments of the present disclosure, a method for manufacturing an interconnect structure includes: forming a first stack on a base structure, the first stack including a first conductive line and a first cap portion which is formed on the first conductive line opposite to the base structure; forming a second stack on the base structure, the second stack being spaced apart from the first stack by a dielectric portion, the second stack including a second conductive line, a second cap portion which is formed on the second conductive line opposite to the base structure, and a lower conductive via which is formed in the second cap portion so as to permit the lower conductive via to be electrically connected to the second conductive line, each of the first cap portion and the second cap portion including a first dielectric material; forming a patterned etch stop layer on the first stack, the second stack and the dielectric portion so that the lower conductive via is exposed from the patterned etch stop layer and the second conductive line is prevented from being exposed from the patterned etch stop layer; and forming an upper conductive via on the lower conductive via so as to permit the upper conductive via to be electrically connected to the second conductive line through the lower conductive via.

In accordance with some embodiments of the present disclosure, the first stack and the second stack are spaced apart from each other in a first direction, and the second cap portion includes two cap parts which are separated from each other by the lower conductive via in a second direction. The second direction is transverse to the first direction.

In accordance with some embodiments of the present disclosure, each of the first cap portion and the second cap portion has an upper surface and a lower surface which are respectively distal from and proximate to the base structure. The upper surface of the first cap portion is flush with the upper surface of the second cap portion. The lower surface of the first cap portion is flush with the lower surface of the second cap portion.

In accordance with some embodiments of the present disclosure, an upper surface of the lower conductive via opposite to the base structure is flush with the upper surface of each of the first cap portion and the second cap portion.

In accordance with some embodiments of the present disclosure, the dielectric portion includes a second dielectric material that is different from the first dielectric material.

In accordance with some embodiments of the present disclosure, the dielectric portion includes an air gap region therein.

In accordance with some embodiments of the present disclosure, the dielectric portion includes an upper region and a lower region which are respectively distal from and proximate to the base structure. A dielectric constant of the upper region is higher than a dielectric constant of the lower region. A height of the lower region is not greater than a height of each of the first conductive line and the second conductive line.

In accordance with some embodiments of the present disclosure, a method for manufacturing an interconnect structure includes: forming a first stack, a second stack and a lower dielectric portion on a base structure, the first stack and the second stack being spaced apart from each other by the lower dielectric portion, each of the first stack and the second stack including a conductive line and a cap portion which is disposed on the conductive line opposite to the base structure, the cap portion including a first dielectric material; performing a replacement process to replace a predetermined part of the cap portion of the second stack with a lower conductive via so as to permit the lower conductive via to be electrically connected to the conductive line of the second stack; after the replacement process, forming an upper dielectric portion to cover the first stack, the second stack and the lower dielectric portion; and forming an upper conductive via which extends through the upper dielectric portion so as to permit the upper conductive via to be electrically connected to the conductive line of the second stack through the lower conductive via.

In accordance with some embodiments of the present disclosure, formation of the upper conductive via includes forming a via opening in the upper dielectric portion to expose the lower conductive via, and forming the upper conductive via in the via opening.

In accordance with some embodiments of the present disclosure, the first stack and the second stack are spaced apart from each other in a first direction, and a dimension of the via opening measured in the first direction is greater than a dimension of the lower conductive via measured in the first direction.

In accordance with some embodiments of the present disclosure, the method, before the replacement process, further includes: forming barrier portions each of which is disposed between the lower dielectric portion and a corresponding one of the first stack and the second stack. The barrier portions includes a dielectric material that is different from the first dielectric material of the cap portion.

In accordance with some embodiments of the present disclosure, the method further includes: forming a liner layer between the upper conductive via and the upper dielectric portion. The liner layer includes tantalum, tantalum nitride, aluminum, aluminum oxide, titanium, titanium nitride, manganese nitride, cobalt, niobium, lead, platinum, nickel, scandium, ruthenium, molybdenum, chromium, titanium tungsten, tungsten nitride, tungsten, iridium, rhodium, graphene, or combinations thereof.

In accordance with some embodiments of the present disclosure, the replacement process includes forming a mask layer on the lower dielectric portion and the cap portion of each of the first stack and the second stack, forming an upper opening in the mask layer to expose the predetermined part of the cap portion of the second stack, removing the predetermined part of the cap portion of the second stack to form a lower opening from which the conductive line of the second stack is exposed, and forming the lower conductive via to fill the lower opening.

In accordance with some embodiments of the present disclosure, the first stack and the second stack are spaced apart from each other in a first direction, and a dimension of the upper opening measured in the first direction is greater than a dimension of the cap portion of the second stack measured in the first direction.

In accordance with some embodiments of the present disclosure, formation of the first stack, the second stack and the dielectric portion includes: sequentially forming a conductive layer and a cap layer on the base structure; performing a patterning process such that the conductive layer is patterned into the conductive line of each of the first stack and the second stack, and the cap layer is patterned into the cap portion of each of the first stack and the second stack; and forming the lower dielectric portion between the first stack and the second stack.

In accordance with some embodiments of the present disclosure, the lower dielectric portion includes a second dielectric material that is different from the first dielectric material.

In accordance with some embodiments of the present disclosure, the lower dielectric portion includes an upper region and a lower region which are respectively distal from and proximate to the base structure. A dielectric constant of the upper region is greater than a dielectric constant of the lower region.

In accordance with some embodiments of the present disclosure, the lower region is an air gap region. Formation of the lower dielectric portion includes forming a sacrificial region between the conductive line of the first stack and the conductive line of the second stack, forming the upper region on the sacrificial region such that the upper region is disposed between the cap portion of the first stack and the cap portion of the second stack, and after formation of the upper region, removing the sacrificial region to form the lower region.

In accordance with some embodiments of the present disclosure, an interface between the upper region and the sacrificial region is at a level not higher than a level of an interface between the cap portion and the conductive line of the first stack relative to the base structure.

In accordance with some embodiments of the present disclosure, an interconnect structure includes: a first stack formed on a base structure, the first stack including a first conductive line and a first cap portion which is formed on the first conductive line opposite to the base structure; a second stack formed on the base structure, the second stack being spaced apart from the first stack by a dielectric portion, the second stack including a second conductive line, a second cap portion which is formed on the second conductive line opposite to the base structure, and a lower conductive via which is formed in the second cap portion so as to permit the lower conductive via to be electrically connected to the second conductive line; an etch stop layer formed on the first stack, the second stack and the dielectric portion so that the etch stop layer is in direct contact with the first cap portion and the second cap portion; and an upper conductive via formed to penetrate the etch stop layer so as to permit the upper conductive via to be electrically connected to the second conductive line through the lower conductive via. Each of the first cap portion and the second cap portion includes a first dielectric material, and the dielectric portion includes a second dielectric material that is absent in each of the first cap portion and the second cap portion.

In accordance with some embodiments of the present disclosure, a method for manufacturing an interconnect structure includes: forming a first stack, a second stack and a dielectric portion on a base structure, the first stack and the second stack being spaced apart from each other by the dielectric portion, each of the first stack and the second stack including a conductive line and a cap portion which is disposed on the conductive line opposite to the base structure, the cap portion including a first dielectric material; performing a replacement process to replace a predetermined part of the cap portion of the second stack with a lower conductive via so as to permit the lower conductive via to be electrically connected to the conductive line of the second stack; after the replacement process, forming a patterned etch stop layer on the first stack, the second stack and the dielectric portion so that the lower conductive via is exposed from the patterned etch stop layer and the conductive line of the second stack is prevented from being exposed from the patterned etch stop layer; and forming an upper conductive via on the lower conductive via so as to permit the upper conductive via to be electrically connected to the conductive line of the second stack through the lower conductive via.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a first stack on a base structure, the first stack including a first conductive line and a first cap portion which is formed on the first conductive line opposite to the base structure;
forming a second stack on the base structure, the second stack being spaced apart from the first stack by a dielectric portion, the second stack including a second conductive line, a second cap portion which is formed on the second conductive line opposite to the base structure, and a lower conductive via which is formed in the second cap portion so as to permit the lower conductive via to be electrically connected to the second conductive line, each of the first cap portion and the second cap portion including a first dielectric material;
forming a patterned etch stop layer on the first stack, the second stack and the dielectric portion so that the lower conductive via is exposed from the patterned etch stop layer and the second conductive line is prevented from being exposed from the patterned etch stop layer; and
forming an upper conductive via on the lower conductive via so as to permit the upper conductive via to be electrically connected to the second conductive line through the lower conductive via.

2. The method as claimed in claim 1, wherein
the first stack and the second stack are spaced apart from each other in a first direction, and
the second cap portion includes two cap parts which are separated from each other by the lower conductive via in a second direction, the second direction being transverse to the first direction.

3. The method as claimed in claim 1, wherein each of the first cap portion and the second cap portion has an upper surface and a lower surface which are respectively distal from and proximate to the base structure, the upper surface of the first cap portion being flush with the upper surface of the second cap portion, the lower surface of the first cap portion being flush with the lower surface of the second cap portion.

4. The method as claimed in claim 3, wherein an upper surface of the lower conductive via opposite to the base structure is flush with the upper surface of each of the first cap portion and the second cap portion.

5. The method as claimed in claim 1, wherein the dielectric portion includes a second dielectric material that is different from the first dielectric material.

6. The method as claimed in claim 1, wherein the dielectric portion includes an air gap region therein.

7. The method as claimed in claim 1, wherein the dielectric portion includes an upper region and a lower region which are respectively distal from and proximate to the base structure, a dielectric constant of the upper region being higher than a dielectric constant of the lower region, a height of the lower region being not greater than a height of each of the first conductive line and the second conductive line.

8. A method for manufacturing an interconnect structure, comprising:
forming a first stack, a second stack and a lower dielectric portion on a base structure, the first stack and the second stack being spaced apart from each other by the lower dielectric portion, each of the first stack and the second stack including a conductive line and a cap portion which is disposed on the conductive line opposite to the base structure, the cap portion including a first dielectric material;
performing a replacement process to replace a predetermined part of the cap portion of the second stack with a lower conductive via so as to permit the lower conductive via to be electrically connected to the conductive line of the second stack;
after the replacement process, forming an upper dielectric portion to cover the first stack, the second stack and the lower dielectric portion; and
forming an upper conductive via which extends through the upper dielectric portion so as to permit the upper conductive via to be electrically connected to the conductive line of the second stack through the lower conductive via.

9. The method as claimed in claim 8, wherein formation of the upper conductive via includes
forming a via opening in the upper dielectric portion to expose the lower conductive via, and
forming the upper conductive via in the via opening.

10. The method as claimed in claim 9, wherein the first stack and the second stack are spaced apart from each other in a first direction, and a dimension of the via opening measured in the first direction is greater than a dimension of the lower conductive via measured in the first direction.

11. The method as claimed in claim 8, before the replacement process, further comprising:
forming barrier portions each of which is disposed between the lower dielectric portion and a corresponding one of the first stack and the second stack, the barrier portions including a dielectric material that is different from the first dielectric material of the cap portion.

12. The method as claimed in claim 8, further comprising:
forming a liner layer between the upper conductive via and the upper dielectric portion, the liner layer including tantalum, tantalum nitride, aluminum, aluminum oxide, titanium, titanium nitride, manganese nitride, cobalt, niobium, lead, platinum, nickel, scandium, ruthenium, molybdenum, chromium, titanium tungsten, tungsten nitride, tungsten, iridium, rhodium, graphene, or combinations thereof.

13. The method as claimed in claim 8, wherein the replacement process includes
forming a mask layer on the lower dielectric portion and the cap portion of each of the first stack and the second stack,
forming an upper opening in the mask layer to expose the predetermined part of the cap portion of the second stack,
removing the predetermined part of the cap portion of the second stack to form a lower opening from which the conductive line of the second stack is exposed, and
forming the lower conductive via to fill the lower opening.

14. The method as claimed in claim 13, wherein the first stack and the second stack are spaced apart from each other in a first direction, and a dimension of the upper opening measured in the first direction is greater than a dimension of the cap portion of the second stack measured in the first direction.

15. The method as claimed in claim 8, wherein formation of the first stack, the second stack and the dielectric portion includes
sequentially forming a conductive layer and a cap layer on the base structure,
performing a patterning process such that the conductive layer is patterned into the conductive line of each of the first stack and the second stack, and the cap layer is patterned into the cap portion of each of the first stack and the second stack, and
forming the lower dielectric portion between the first stack and the second stack.

16. The method as claimed in claim 8, wherein the lower dielectric portion includes a second dielectric material that is different from the first dielectric material.

17. The method as claimed in claim 8, wherein the lower dielectric portion includes an upper region and a lower region which are respectively distal from and proximate to the base structure, a dielectric constant of the upper region being greater than a dielectric constant of the lower region.

18. The method as claimed in claim 17, wherein
the lower region is an air gap region, and
formation of the lower dielectric portion includes
forming a sacrificial region between the conductive line of the first stack and the conductive line of the second stack,
forming the upper region on the sacrificial region such that the upper region is disposed between the cap portion of the first stack and the cap portion of the second stack, and
after formation of the upper region, removing the sacrificial region to form the lower region.

19. The method as claimed in claim 18, wherein an interface between the upper region and the sacrificial region is at a level not higher than a level of an interface between the cap portion and the conductive line of the first stack relative to the base structure.

20. An interconnect structure, comprising:
a first stack formed on a base structure, the first stack including a first conductive line and a first cap portion which is formed on the first conductive line opposite to the base structure;
a second stack formed on the base structure, the second stack being spaced apart from the first stack by a dielectric portion, the second stack including a second conductive line, a second cap portion which is formed on the second conductive line opposite to the base structure, and a lower conductive via which is formed in the second cap portion so as to permit the lower conductive via to be electrically connected to the second conductive line;
an etch stop layer formed on the first stack, the second stack and the dielectric portion so that the etch stop layer is in direct contact with the first cap portion and the second cap portion; and
an upper conductive via formed to penetrate the etch stop layer so as to permit the upper conductive via to be electrically connected to the second conductive line through the lower conductive via,
each of the first cap portion and the second cap portion including a first dielectric material, the dielectric portion including a second dielectric material that is absent in each of the first cap portion and the second cap portion.
